(19) United States
(12) Patent Application Publication
(10) Pub. No.: US 2020/0192450 A1
(43) Pub. Date: Jun. 18, 2020

(54) POWER DEVICE AND METHOD FOR OPERATING A POWER DEVICE

(71) Applicant: Rohde & Schwarz GmbH & Co. KG, Munich (DE)

(72) Inventors: Philipp Weigell, Munich (DE); Sascha Kunisch, Munich (DE); Christian Koemmling, Munich (DE)

(73) Assignee: Rohde & Schwarz GmbH & Co. KG, Munich (DE)

(21) Appl. No.: 16/221,141

(22) Filed: Dec. 14, 2018

(51) Int. Cl. G06F 1/28; G01R 21/06; G01R 31/382

(52) U.S. Cl. CPC G06F 1/28; G01R 31/382; G01R 21/06

(57) ABSTRACT

A power device is described that comprises an input for receiving an inputted signal, an output for outputting an outputted signal, a sensor unit for sensing at least one parameter assigned to the power device, and a calibration unit for providing settings of the power device. The sensor unit is connected with the calibration unit. The calibration unit is configured to adjust the settings of the power device based on the at least one parameter sensed. Further, a method for operating a power device is described.

### FIELD OF THE DISCLOSURE

Embodiments of the present disclosure relate generally to a power device. Furthermore, embodiments of the present disclosure generally relate to a method for operating a power device to output a stable outputted signal.

### BACKGROUND

Modern electronic devices having electronic circuits, for instance an integrated circuit (IC), require an accurate power supply so that it is necessary to provide current, voltage and/or power with a high accuracy. So far, power supply devices or rather power converter devices are used which are built by high-end components, namely hardware components, that provide a high accuracy over a large temperature range as well as a large humidity range so as to ensure that a stable current, voltage and/or power are/is outputted irrespective of the current temperature and/or humidity conditions.

However, these power devices, particularly the power supply devices or rather power converter devices, are very expensive due to the high-end hardware components used for ensuring the stable output of the respective signal.

Therefore, there is a need for a cost-efficient possibility to provide stable current, voltage and/or power over a large temperature and/or humidity range.

### SUMMARY

Embodiments of the present disclosure provide a power device comprising:

an input for receiving an inputted signal;

an output for outputting an outputted signal;

a sensor unit for sensing at least one parameter assigned to the power device; and

a calibration unit for providing settings of the power device,

wherein the sensor unit is connected with the calibration unit, and wherein the calibration unit is configured to adjust the settings of the power device based on the at least one parameter sensed.

Further, embodiments of the present disclosure provide a method for operating a power device to output a stable outputted signal, with the following steps:

receiving an input signal via an input of the power device;

sensing at least one parameter assigned to the power device;

adjusting settings of the power device based on the at least one parameter sensed;

processing the input signal with the adjusted settings; and

outputting a stable outputted signal that is adapted to the at least one parameter sensed due to the adjusted settings that were adjusted based on the at least one parameter sensed.

Accordingly, a power device as well as a method for operating such a power device are provided that use a control for adapting the respective settings of the power device to ensure a stable outputted signal. The control can be software-based since the at least one parameter sensed by the sensor unit is processed appropriately so as to adapt the calibration settings of the power device. Accordingly, expensive hardware components, namely high-end components, are not necessary anymore due to the fact that the power device is adapted to the current operation conditions of the power device. The desired accuracy of the power device can be ensured since a dynamic adaption of the settings of the power device is provided with respect to the operating conditions of the power device. In fact, the respective value of the at least one parameter sensed is taken into account for adapting the respective (calibration) settings of the power device. This means that a higher value of the same parameter sensed may result in a different (calibration) setting of the power device.

Hence, the at least one parameter sensed is monitored by the sensor unit, for example at critical positions of the power device. Based upon the monitoring the (calibration) settings are dynamically adapted in an appropriate manner so as to react on changing operation conditions. Accordingly, the outputted signal is improved with regard to its accuracy.

An aspect provides that the sensor unit is configured to sense at least one environmental parameter of the power device. Thus, the operation conditions are merely defined by the environmental conditions since the sensor unit senses environmental parameters of the power device, for example at critical locations.

For instance, the sensor unit comprises at least one of a temperature sensor, a humidity sensor, a pressure sensor, a gravity sensor and an acceleration sensor. Thus, the different environmental parameters like temperature, humidity, pressure, gravity (attitude) or rather acceleration can be sensed by the sensor unit which might have an influence on the accuracy of the power device.

Furthermore, the settings may be assigned to at least one of noise and ripple of the outputted signal. Noise and/or ripple may depend on the at least one parameter sensed previously wherein noise and/or ripple typically have a negative impact on the accuracy of the outputted signal as they cause undesired fluctuations. By taking the respective parameter sensed into account for adapting the settings of the power device, it is ensured that the occurrence of noise and/or ripple can be minimized so as to ensure that the outputted signal is as stable as possible. In other words, the settings are adapted so as to minimize the undesired fluctuations.

Another aspect provides that the input and the output are connected with each other via a transmission line, wherein the calibration unit is connected with the transmission line to adapt the characteristics of a signal processed by the power device. The signal processed is the signal that has been converted from the inputted signal. The processed signal relates to the outputted signal once it has been adapted according to the adapted settings. This means that the inputted signal is processed internally by the power device so as to adapt the characteristics of the respective signal such that a stable signal is provided that is outputted at the output.

Generally, the output of the power device may be connected with a separately formed electronic device that has a sensitive electronic circuit with regard to power fluctuations, for example an integrated circuit.

According to another aspect, at least one adjustable processing member is provided in the transmission line that is connected with the calibration unit, wherein the calibration unit is configured to adjust the at least one adjustable processing member based on the at least one parameter sensed. The adjustable processing member is provided to process the inputted signal appropriately so as to adapt the characteristics of the inputted signal with respect to the at least one parameter sensed. Therefore, the calibration unit controls the at least one adjustable processing member based on the parameter sensed by the sensor unit that is connected with the calibration unit. Accordingly, it is ensured that the inputted signal is adapted in a desired manner.

The at least one adjustable processing member may be part of the calibration unit so that the at least one adjustable processing member is integrated in the calibration unit.

Moreover, the at least one adjustable processing member may influence the current, the voltage and/or the power of the signal processed. Moreover, the at least one adjustable processing member may influence the resistance value of the power device, for example the transmission line.

The at least one adjustable processing member is adapted based upon (calibration) settings which are adapted with respect to the at least one parameter sensed.

The power device may be configured to dynamically adapt the settings of the power device based on the at least one parameter sensed. Thus, the respective operation parameters of the power device can be adapted dynamically so as to react on changing operation conditions to which the power device is exposed, for example live, namely during operation of the power device. Therefore, changing temperature or rather changing humidity may be taken into account during operation of the power device.

In other words, changing environmental conditions like changing temperature and/or changing humidity during operation of the power device does not have any effect on the accuracy of the outputted signal since the respective changing conditions are compensated internally by the power device due to the adaption of the settings of the power device. Hence, a software-based compensation is provided.

Furthermore, the calibration unit may be configured to adjust the settings of the power device such that the outputted signal is stable. Accordingly, a stable outputted signal is ensured irrespective of any changing operation conditions. This is ensured without the need of expensive high-end components since the settings of the power device, for example the calibration settings, are adapted based on the value of the at least one parameter sensed.

For instance, the calibration unit is configured to adjust at least one of current, voltage, resistance and power based on the at least one parameter sensed. Therefore, the calibration unit may interact with an appropriate adjustable processing member to adjust the respective parameter of the signal processed. For instance, the adjustable processing parameter may be a resistor being adjustable wherein the calibration unit sets the adjustable resistor in an appropriate manner so as to adapt current, voltage and/or power of the signal processed in a desired manner.

Accordingly, the outputted signal may be at least one of a current signal, a voltage signal and a power signal. The outputted signal may be set by an operator of the power device in a desired manner.

Another aspect provides that the power device is configured to adapt the outputted signal based on the at least one parameter sensed by the sensor unit and calibration data assigned to the at least one parameter sensed. Thus, calibration data is provided that can be accessed internally so as to adapt the settings of the power device due to the at least one parameter sensed.

For instance, a memory is provided that is assigned to the calibration unit. The memory may comprise data that can be accessed by the calibration unit appropriately so to adapt the settings of the power device.

Moreover, the respective data assigned to the settings may be loaded by the calibration unit.

According to an aspect, at least two data sets of calibration data are stored in the memory. The different data sets may be assigned to different values of the at least one parameter sensed so as to ensure that respective data sets are provided for the different values of the parameter sensed.

Moreover, the data sets may be assigned to different ranges of the parameter sensed so that a first data set may be assigned to high temperature whereas the second data set may be assigned to low temperatures. Thus, a certain threshold value with regard to temperature may be provided that is taken into account when deciding which kind of data set is used for adapting the settings of the power device.

This also applies for any other environmental parameter that may be sensed by the sensor unit as mentioned above.

According to another embodiment, at least one look-up table is stored in the memory. The look-up table may also be accessed by the calibration unit as described above. The look-up table may comprise several values with regard to the parameters sensed by the sensor unit so that the calibration unit is adapted to access the look-up table for reading out the appropriate settings assigned to the at least one parameter sensed, for example the respective value.

Furthermore, the look-up table may be a tensor or any other high-dimensional table so that more than one parameter sensed may be taken into account for obtaining the respective settings.

Alternatively, several look-up tables may be stored that are accessed simultaneously or rather subsequently. For instance, each environmental parameter may be assigned to its own look-up table.

Otherwise, each environmental parameter may be assigned to a dimension of the high-dimensional table.

Another embodiment provides that a feedback sensor is provided that is configured to measure the outputted signal. Hence, a feedback signal may be provided that is taken into account for adapting the settings. Therefore, a feedback loop may be provided that is established by the feedback sensor.

The feedback sensor may be connected with at least one of the sensor unit and the calibration unit. Thus, the feedback signal is forwarded to the sensor unit and/or the calibration unit so that the respective component takes the feedback signal into account for further processing.

Thus, the adjustment or rather the adaption of the settings of the power device may be adapted in response to the outputted signal measured and forwarded via the feedback sensor.

The input may be at least one of a direct current input and an alternating current input. Moreover, the output may be at least one of a direct current output and an alternating current output. Thus, AC current and/or DC current may be processed by the power device.

Furthermore, the power device is at least one of a power supply device and a power converter device. Thus, AC current may be inputted which is outputted in case of a power supply device. Alternatively, AC current may be inputted that is converted by the power device, namely the power converter device, into a DC current. The same applies for DC currents being inputted.

Generally, the outputted signal is substantially ripple-free and/or noise-free. In other words, the contributions of ripples and/or noise are reduced to a minimum due to the adaption of the settings of the power device.

The (calibration) settings applied may correspond to different operation parameters of the power device.

Accordingly, the (calibration) settings are selected based upon the at least one parameter sensed to ensure a stable and accurate outputted signal. However, the signal strength of the outputted signal is not adapted with respect to the at least one parameter sensed such as increasing the outputted power due to a certain parameter sensed. In fact, the internal processing of the signal is adapted to provide a stable outputted signal without any deviations or rather fluctuations that might impair the accuracy of the outputted signal.

Therefore, electronic devices may be connected to the power device which are sensitive with respect to the accuracy of their input signal.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a representative embodiment of a power device according to the present disclosure,

FIG. 2 shows a flow-chart illustrating a method for operating a power device according to the present disclosure, and

FIG. 3 shows an overview of several diagrams illustrating different calibration data.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

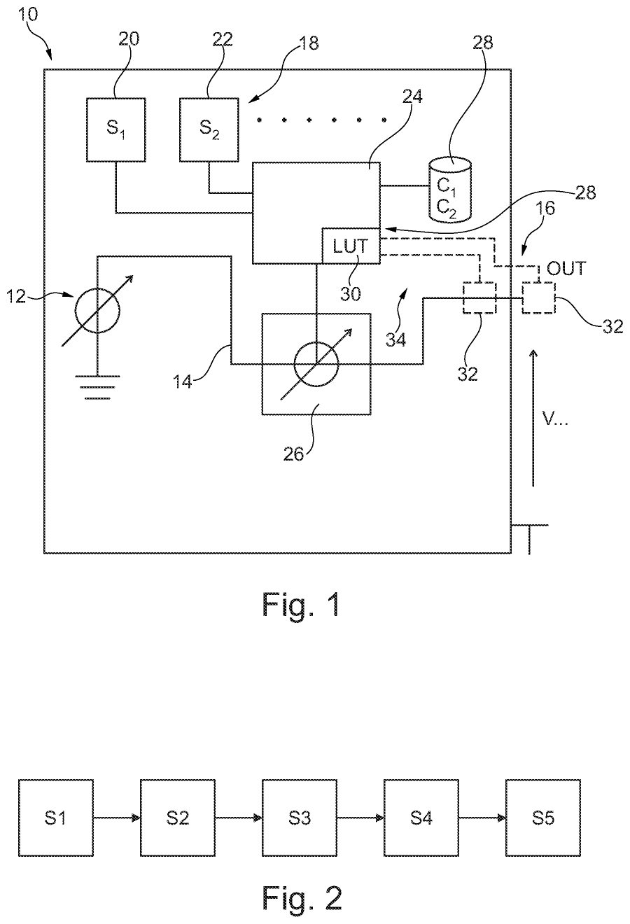

In FIG. 1, a power device 10 is shown that has an enhanced calibration functionality as the calibration settings can be adapted automatically by the power device 10 and during operation. In the embodiment shown, the power device 10 comprises an input 12 for receiving an inputted signal. The input 12 is connected with a transmission line 14 that forwards the inputted signal to an output 16 for outputting an outputted signal wherein the respective signal is processed by the power device 10 while being forwarded to the output 16.

The power device 10 also includes a sensor unit 18 configured for sensing at least one parameter that is assigned to the power device 10, for example an environmental parameter of the environment to which the power device 10 is exposed during operation. Thus, the respective operation conditions of the power device 10 may be sensed by the sensor unit 18.

In the shown embodiment, the sensor unit 18 has at least two sensors 20, 22 which may be established by at least one of a temperature sensor, humidity sensor, a pressure sensor, a gravity sensor and an acceleration sensor. Of course, any number (e.g., 1-N) of sensors may be included with sensor unit 18.

Thus, the sensor unit 18 is generally configured to sense the at least one environmental parameter of the power device 10 as mentioned above.

The power device 10 further includes a calibrator or calibration unit 24 for providing settings according to which the power device 10 processes the inputted signal. The calibration unit 24 is connected with the sensor unit 18 as well as an adjustable processing member 26 that is provided in the transmission line 14. In some embodiments, the adjustable processing member 26 may be part of the calibration unit 24.

In some embodiments, the calibration unit 24 is assigned to a memory 28 of the power device 10 in which at least two data sets C1, C2 of calibration data are stored. Alternatively or additionally, the calibration unit 24 may be assigned to at least one look-up table 30 that may also be stored in the memory 28.

The power device 10 shown in FIG. 1 is generally configured to adapt the (calibration) settings of the power device 10 so as to adapt the setting how the power device 10 processes the respective signal. This will be described hereinafter with reference to FIG. 2 illustrating a method for operating the power device 10.

In a first step S1, a signal is received via the input 12 of the power device 10, namely the inputted signal.

In a second step S2, at least one (environmental) parameter of the power device 10 is sensed via the sensor unit 18 wherein the at least one (environmental) parameter is assigned to the power device 10. Environmental conditions defining the operation conditions of the power device 10 are sensed via the sensor unit 18, for example the respective sensors 20, 22.

The at least one parameter sensed is forwarded to the calibration unit 24 which in turn adjusts or rather adapts the (calibration) settings of the power device 10 based upon the at least one parameter sensed in a third step S3.

The calibration unit 24 may access the memory 28 or rather the look-up table 30 that might be stored in the memory 28 so as to obtain (calibration) data assigned to the at least one parameter sensed, namely the value or rather a range of the at least one parameter sensed. In other words, the calibration unit 24 obtains the respective (calibration) settings from the memory 28.

Depending on the (calibration) data obtained, the calibration unit 24 may adjust the at least one adjustable processing member 26 in the transmission line 14 so that the signal processed via the transmission line 14 is adapted by the at least one adjustable processing member 26 or rather the calibration unit 24 so that the characteristics are adapted with respect to the at least one (environmental) parameter sensed.

Accordingly, the inputted signal is processed with the adjusted or rather adapted (calibration) settings in a fourth step S4 based upon the at least one (environmental) parameter sensed by the sensor unit 18. This ensures that the appropriate (calibration) settings of the power device 10 are chosen or rather selected, for example in an automatic manner, that ensure best processing characteristics.

In a fifth step S5, the processed signal is outputted as an outputted signal, wherein the outputted signal is stable so that inter alia noise and/or ripples are minimized.

This can be ensured due to the adaption of the settings to the at least one parameter sensed, which are used for processing the inputted signal.

The respective settings were adjusted based on the at least one parameter sensed previously by the sensor unit 18 so that the settings of the power device 10 for adapting or rather adjusting the processed signals were set automatically by the power device 10 with regard to the environmental conditions or rather the operational conditions of the power device 10.

Hence, the power device 10 is generally configured to dynamically adapt its settings in an automatic manner based on the at least one parameter sensed. In other words, the settings are adjusted such that the outputted signal at the output 16 is a stable one having minimized noise and/or ripples.

Accordingly, environmental influences on the stability of the outputted signal are compensated by the power device 10 due to the automatic adaption of the (calibration) settings. As the respective (calibration) settings are accessed or rather loaded by the calibration unit 24, a software-based adaption of signal processing is ensured so that no manual input is required for adapting the (calibration) settings.

Therefore, the usability is improved.

Moreover, the power device 10 may have a feedback sensor 32 that is provided to measure the outputted signal. As indicated by the dashed lines, the feedback sensor 32 may be an external one or rather an integrated one. The feedback sensor 32 may be connected with at least one of the sensor unit 18 and the calibration unit 24 so as to forward the signal sensed to the respective component of the power device 10, namely a feedback signal.

Accordingly, a feedback line 34 is provided which can be used for adjusting the settings of the power device 10 more accurately since the respective settings are adapted with respect to the environmental parameters sensed by the sensor unit 18, for example its respective sensors 20, 22. as well as the feedback sensor 32 which may monitor whether or not the adaption of the (calibration) settings provide the desired stable outputted signal.

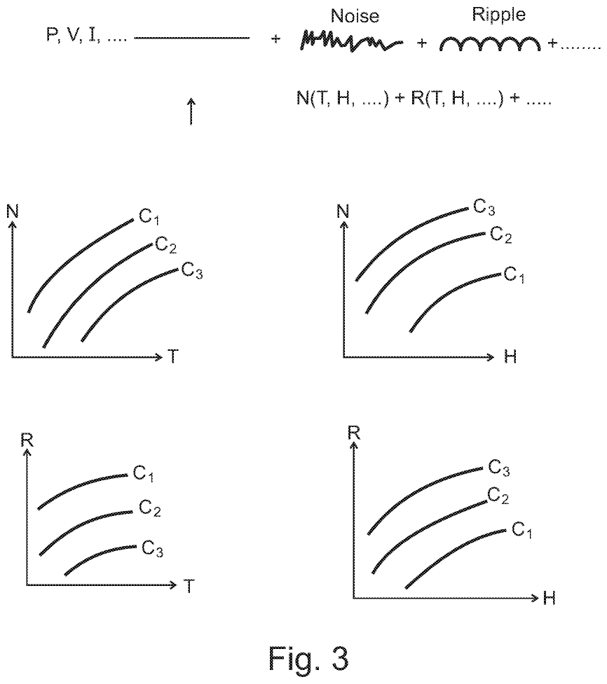

As shown in FIG. 3, the respective outputted signal may comprise noise and/or ripple wherein the respective settings are assigned to at least one of noise and ripple so that the settings are adapted such that noise and/or ripple are minimized appropriately.

In other words, it has been found that noise as well as ripple may depend on the parameters sensed, namely temperature, humidity, pressure, gravity and/or acceleration, etc. By adapting the respective settings, it is ensured that noise and/or ripple influencing the accuracy of the outputted can be minimized appropriately so that a stable outputted signal is provided.

In FIG. 3, two diagrams are shown that illustrate different sets of calibration data C1, C2, C3 for noise depending on temperature T and humidity H. In the same manner, calibration data C1, C2, C3 may be provided for ripple depending on temperature T and humidity H.

The respective data is illustrated by diagrams. In general, the data may be stored in the at least one look-up table 30. The at least one look-up table 30 may have several dimensions so that a tensor or a higher dimensional table is provided. The dimension of the table is assigned to the number of (environmental) parameters taken into account by the sensor unit 18.

Other influences than noise and ripple may also be compensated by the software-based adaption of the (calibration) settings since the settings were determined (previously) under the respective conditions. Thus, it can be ensured that all influences yielding fluctuations in the outputted signal are compensated simultaneously.

As shown in FIG. 3, the respective calibration settings or rather calibration data C1, C2, C3 loaded based upon the at least one parameter sensed correspond to calibration curves

An electronic device that is connected with the power device 10 may obtain a stable signal, for instance a stable current signal, a stable voltage signal and/or a stable power signal.

This ensures that the electronic device connected to the power device 10 can be operated in an appropriate manner due to the fact that noise or rather ripple is minimized so as to minimize the negative influence on the electronic circuits of the electronic device connected with the power device 10.

A cost-efficient possibility is provided to ensure a stable outputted signal without the need for high-end or rather expensive hardware components due to the fact that a software-based internal control is provided for ensuring a stable outputted signal.

Generally, the power device 10 in some embodiments may be a power converter device that converts alternating current into direct current or vice versa or rather a power supply device that provides power for supplying an electronic device connected to the power device 10 with power, for example wherein the strength of the power is adapted.

It should be understood that each block of any of the block diagrams and/or flowchart illustrations, respectively, described herein and/or illustrated in the FIGURES may be implemented in part by computer program instructions, e.g., as logical steps or operations executing on a processor in a computing system. These computer program instructions may be loaded onto a computer, such as a special purpose computer or other programmable data processing apparatus to produce a specifically-configured machine, such that the instructions which execute on the computer or other programmable data processing apparatus implement the functions specified in the flowchart block, block diagrams, descriptions herein, etc. The term computer can include any processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), or the like, or any combinations thereof.

In some embodiments, one or more of the components of the power device 10, such as the sensor unit 18, the calibration unit 24, etc., includes one or more computing devices associated with a memory storing logic modules and/or instructions for carrying out the function(s) of power device and/or any of its sub-units, either separately or in any combination. In an embodiment, one or more of the components of the power device 10 includes combinations of circuits and computer program products having software or firmware instructions stored on one or more computer readable memories that work together to cause the power device to perform one or more methodologies or technologies described herein.

The present application may also reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A power device comprising:
an input configured for receiving an inputted signal;
an output configured for outputting an outputted signal;
a sensor unit configured for sensing at least one parameter assigned to the power device; and
a calibration unit configured for providing settings of the power device,
wherein the sensor unit is connected with the calibration unit, and
wherein the calibration unit is configured to adjust the settings of the power device based on the at least one parameter sensed.

2. The power device according to claim 1, wherein the sensor unit is configured to sense at least one environmental parameter of the power device.

3. The power device according to claim 1, wherein the sensor unit comprises at least one of a temperature sensor, a humidity sensor, a pressure sensor, a gravity sensor and an acceleration sensor.

4. The power device according to claim 1, wherein the settings are assigned to at least one of noise and ripple of the outputted signal.

5. The power device according to claim 1, wherein the input and the output are connected with each other via a transmission line, and wherein the calibration unit is connected with the transmission line to adapt the characteristics of a signal processed by the power device.

6. The power device according to claim 1, wherein at least one adjustable processing member is provided in the transmission line that is connected with the calibration unit, and wherein the calibration unit is configured to adjust the at least one adjustable processing member based on the at least one parameter sensed.

7. The power device according to claim 1, wherein the power device is configured to dynamically adapt the settings of the power device based on the at least one parameter sensed.

8. The power device according to claim 1, wherein the calibration unit is configured to adjust the settings of the power device such that the outputted signal is stable.

9. The power device according to claim 1, wherein the calibration unit is configured to adjust at least one of current, voltage, resistance and power based on the at least one parameter sensed.

10. The power device according to claim 1, wherein the outputted signal is at least one of a current signal, a voltage signal and a power signal.

11. The power device according to claim 1, wherein the power device is configured to adapt the outputted signal based on the at least one parameter sensed by the sensor unit and calibration data assigned to the at least one parameter sensed.

12. The power device according to claim 1, wherein a memory is provided that is assigned to the calibration unit.

13. The power device according to claim 12, wherein at least two data sets of calibration data are stored in the memory.

14. The power device according to claim 12, wherein at least one look-up table is stored in the memory.

15. The power device according to claim 1, wherein a feedback sensor is provided that is configured to measure the outputted signal.

16. The power device according to claim 15, wherein the feedback sensor is connected with at least one of the sensor unit and the calibration unit.

17. The power device according to claim 1, wherein the input is at least one of a direct current input and an alternating current input, and wherein the output is at least one of a direct current output and an alternating current output.

18. The power device according to claim 1, wherein the power device is at least one of a power supply device and a power converter device.

19. A method for operating a power device to output a stable outputted signal, with the following steps:
receiving an input signal via an input of the power device;
sensing at least one parameter assigned to the power device;
adjusting settings of the power device based on the at least one parameter sensed;
processing the inputted signal with the adjusted settings; and
outputting a stable outputted signal that is adapted to the at least one parameter sensed due to the adjusted settings that were adjusted based on the at least one parameter sensed.
